(19) United States
(12) Patent Application Publication
(10) Pub. No.: US 2010/0323458 A1
(43) Pub. Date: Dec. 23, 2010

(54) METHOD FOR MAKING P(VDF/TrFE) COPOLYMER LAYER SENSORS, AND CORRESPONDING SENSOR

(75) Inventors: Lionel Fritsch, St. Etienne De Crossey (FR); Philippe Gibert, St. Etienne De Crossey (FR); Claire Vacher, La Valette Du Var (FR)

Correspondence Address: LOWE HAUPTMAN HAM & BERNER, LLP, 1700 DIAGONAL ROAD, SUITE 300, ALEXANDRIA, VA, 22314, US

(73) Assignee: E2V SEMICONDUCTORS, SAINT EGREVE (FR)

(21) Appl. No.: 12/808,728

(22) PCT Filed: Dec. 11, 2008
(86) PCT No.: PCT/EP2008/067289

§ 371 Date: Jul. 19, 2010

(30) Foreign Application Priority Data
Dec. 21, 2007 (FR) 0709031

(51) Int. Cl. H01L 21/70; G01H 11/06

(52) U.S. Cl. 438/3; 73/658; 438/48; 257/E21.532

(57) ABSTRACT

The invention relates to the manufacture of a matrix sensor using a sensitive layer of a ferroelectric P(VDF/TrFE) copolymer, deposited on an integrated circuit. In order to simplify the manufacture and improve the yields, deposited first on the integrated circuit is a first layer of titanium and it is etched in order to form a matrix array of electrodes electrically connected to the integrated circuit; next, a P(VDF/TrFE) copolymer comprising a small proportion of around 1 to 10% of a second polymer that favors the adhesion of the P(VDF/TrFE) copolymer is deposited on the integrated circuit; the polymer is either underneath the P(VDF/TrFE) or blended therewith. The copolymer and its adhesion promoter are etched in a single step, and finally a second conductive layer is deposited and it is etched in order to form a counter electrode for the whole of the matrix array. For use in ultrasonic image sensors.

### RELATED APPLICATIONS

The present application is based on International Application Number PCT/EP2008/067289, filed Dec. 11, 2008, and claims priority from French Application Number 0709031, filed Dec. 21, 2007, the disclosures of which are hereby incorporated by reference herein in their entirety.

### FIELD OF THE INVENTION

The invention relates to the manufacture of integrated electronic circuits using a ferroelectric polymer layer, such as sensors of physical quantities, the operation of which is based on the piezoelectric or pyroelectric properties of the ferroelectric polymer layer.

### BACKGROUND OF THE INVENTION

Such sensors may be constituted in the form of a matrix of elementary ferroelectric detectors making it possible to establish an image or a mapping of pressures or temperatures applied to the surface of the sensor. The matrix of detectors is based on an electronic integrated circuit which individually collects the electric charges or electric charge variations generated by each elementary detector, so as to be able to transmit at the output of the sensor a set of electrical signals that represent the detailed image of the field of temperatures or of pressures applied to the whole of the matrix. They can be used, for example, for ultrasound imaging, or else for the detection of fingerprints.

The manufacture of sensors of this type is carried out in two phases: in a first phase an integrated circuit of standard technology, for example a CMOS technology, is produced, which technology has the advantage of consuming little power and of being very widely used with well-controlled manufacturing processes. And in a second phase, known as a post-process phase, the layers necessary for constituting the matrix of elementary ferroelectric detectors, that is to say at least one first conductive layer that forms individual elementary electrodes connected to the subjacent integrated circuit, a layer of ferroelectric material, and a second conductive layer that forms a counter electrode for the whole of the matrix, are deposited and etched. The elementary detectors are actually essentially constituted by individual capacitors, the ferroelectric layer of which constitutes a pressure-sensitive or temperature-sensitive dielectric.

Although the technology of integrated circuits is very well controlled today, the technology of the post-process phase is tricky to control. Specifically, the known ferroelectric layers are either ceramics that have very good pyroelectricity or piezoelectricity properties, but are expensive to use and poorly suited to depositions on integrated circuits, or crystalline polymer layers, which are a lot less expensive and simpler to use but that have worse pyroelectricity or piezoelectricity properties.

The technical developments in the research of crystalline polymers having the best possible pyroelectric or piezoelectric coefficients and that can be deposited as a flat thin film have led to a copolymer being developed which is satisfactory from this point of view and which is poly(vinylidene difluoride/trifluoroethylene), abbreviated in the form P(VDF/TrFE). The proportion of trifluoroethylene is around 20% to 35% in the copolymer, the remainder is vinylidene difluoride. The truly pyroelectric or piezoelectric compound is the polyvinylidene difluoride (PVDF) which is of crystalline nature. The trifluoroethylene is there to prevent the vinylidene difluoride from polymerizing in the form of helical chains which would not be suitable for the use that it is desired to make thereof. In order to achieve this effect of preventing helical rotation, it is necessary to have a relatively high percentage of trifluoroethylene intimately mixed with the vinylidene difluoride, without, however, deteriorating the crystalline and ferroelectric properties of the PVDF, that is to say its ability to be electrically polarized; 20% to 35% of trifluoroethylene is a reasonable number from this point of view.

Unfortunately, the presence of this large amount of trifluoroethylene in the copolymer proves troublesome in the sense that it greatly reduces the adhesion of the copolymer layer to the integrated circuit. The manufacturing yields therefore drop and the service life of the sensors does also.

In order to overcome this drawback, it has already been proposed to interpose, between the P(VDF/TrFE) layer and the integrated circuit, a layer of polyimide, or better still a layer of bonding resist such as polymethyl methacrylate (abbreviated to PMMA). This layer, for example with a thickness of one micrometer, was photoetched, after which the first conductive layer (electrodes of elementary capacitors) was deposited then etched; the P(VDF/TrFE) was then deposited, as a layer having a thickness of 1 to 10 micrometers, polymerized, then photoetched; finally the second conductive layer (counter electrode) was deposited then etched.

The set of these operations comprised four or more often five photoetching operations. By using a sublayer of PMMA mixed with photosensitive components, this sublayer could be etched directly without having to first deposit a photoresist. But the set remained expensive in terms of the number of manufacturing operations for the phase of producing the sensitive detectors.

Furthermore, certain peripheral zones of P(VDF/TrFE) were inevitably in direct contact with the integrated circuit, without an intermediate layer of PMMA. These zones where the layer of P(VDF/TrFE) was in direct contact with the subjacent integrated circuit were limited in surface area, but they constituted zones of brittleness and of possible detachment of the P(VDF/TrFE) layer, reducing the manufacturing yields and the service life of the products.

Moreover, this PMMA layer could easily be deteriorated in the electrode etching steps, notably in the phases of removal of photoresist after etching of the metal, which made it necessary to use non-standard etching processes for these electrodes.

This is why a novel process is proposed according to the invention which overall reduces the drawbacks of the prior art and which notably makes it possible to minimize the number of steps of the process after the manufacture of the subjacent integrated circuit, while improving the production yields and the service life of the products.

### SUMMARY OF THE INVENTION

The process according to the invention is a process for manufacturing a matrix sensor using a sensitive layer of a ferroelectric P(VDF/TrFE) copolymer, deposited on an integrated circuit, characterized in that it comprises the succession of the following steps:
deposition on the integrated circuit of a first conductive layer and etching of this layer in order to form a matrix array of electrodes electrically connected to the integrated circuit;
deposition of an P(VDF/TrFE) copolymer dissolved in a solvent and also a small proportion of less than 10%, preferably between 1 and 10%, of a second polymer that favors the adhesion of the P(VDF/TrFE) copolymer on the integrated circuit, and drying at high temperature in order to crystallize the copolymer;
a single step of photoetching of the crystalline P(VDF/TrFE) copolymer layer removing the copolymer and the second polymer in the regions where the copolymer should not be retained; and
deposition of a second conductive layer and etching of this layer in order to form a counter electrode for the whole of the matrix array.

The small proportion of the second polymer that favors the adhesion is:
either constituted by a thin layer of second polymer inserted between the integrated circuit and the P(VDF/TrFE) copolymer, this thin layer having a height of less than 10% of the height of the P(VDF/TrFE) layer, typically 0.1 to 0.2 micrometers in thickness for a height of 2 micrometers of the P(VDF/TrFE); the height is defined after drying of the copolymer and of the second polymer;
or intimately mixed with the P(VDF/TrFE) copolymer in a weight proportion between 0.5% and 5%, preferably around 1%.

The second adhesion-promoting polymer is, as will be seen, a polymer of amorphous and non-crystalline nature, which is a priori in contradiction with the idea of inserting it between the lower electrodes and the crystalline copolymer and in contradiction with the idea of mixing it with the crystalline copolymer, but the proportion of this second polymer is low enough, whether this is in terms of the ratio of layer heights or in terms of proportion in the mixture, not to significantly deteriorate the properties of pressure-sensitivity or temperature-sensitivity of the sensor components thus manufactured.

The second polymer is preferably polymethyl methacrylate (PMMA), or else a polymer that has similar properties sold by Fujifilm under the name CT4000. The solvent of these polymers, for the thin-film deposition, is in practice polypropylene glycol monomethyl ether acetate or ethyl 3-ethoxypropionate. CT4000 is the preferred substance in the case where the second polymer is deposited prior to the deposition of P(VDF/TrFE).

The electrodes are preferably made of titanium. The contact pads of the sensor, for the connection with the outside, are preferably made of aluminum (they are formed during the manufacture of the integrated circuit but must be exposed at the end of the post-process steps).

The etching of the titanium is preferably a plasma etching and the plasma used may be a BCl₃/SF₆ or SF₆ or SF₆/O₂ mixture. Such an etching is more precise than wet chemical etching.

The etching of the P(VDF/TrFE), and the simultaneous etching of the adhesion-promoting polymer, is preferably carried out by oxygen plasma and fluorine plasma.

Besides the process which has just been summarized, the invention also relates to a sensor comprising a matrix of pressure-sensitive or temperature-sensitive detectors, which matrix is deposited on an electronic integrated circuit, in which each detector is constituted by a capacitor formed by a first conductive electrode, a second conductive electrode and a ferroelectric layer of P(VDF/TrFE) copolymer between the electrodes, characterized in that the ferroelectric layer comprises a second adhesion-promoting polymer in a proportion of less than 10%, preferably polymethyl methacrylate, deposited under the copolymer or blended with the latter.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIGS. 1 (1a to 1c) and 2 (2a to 2d) represent the successive steps for formation of ferroelectric elementary capacitors in the process of the prior art;

FIG. 3 (3a to 3e) represents the corresponding successive steps of the process according to the invention.

### DESCRIPTION OF PREFERRED EMBODIMENTS

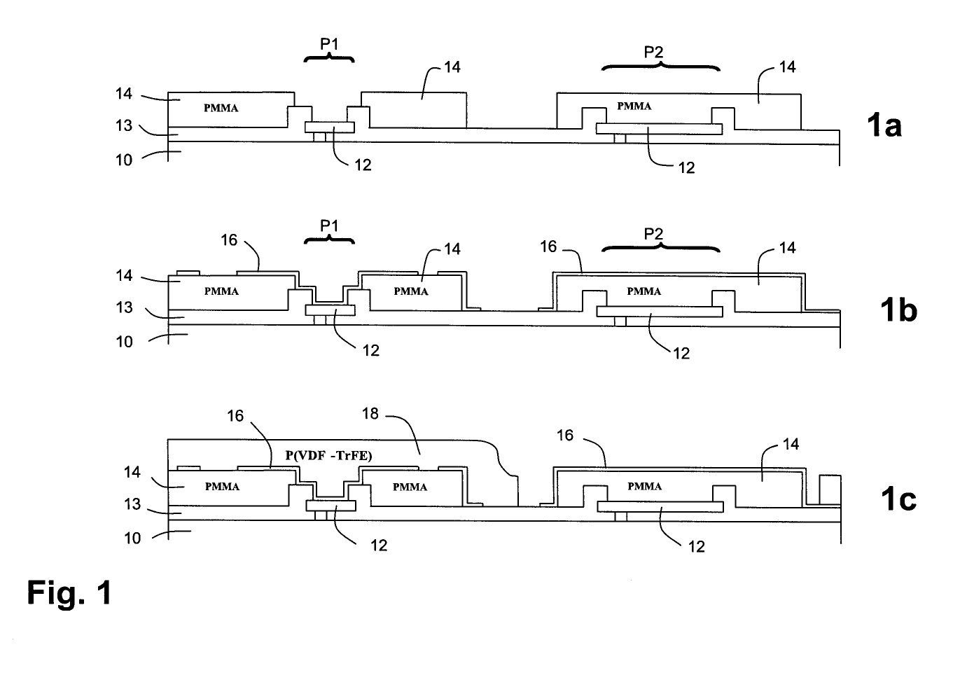

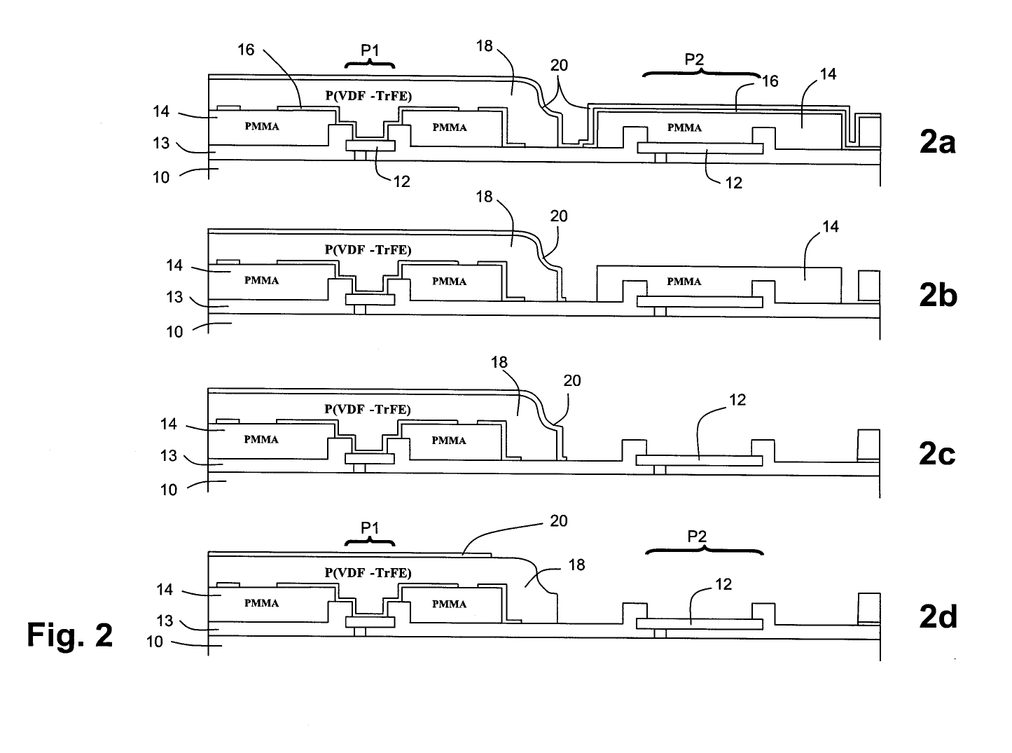

The manufacturing process of the prior art is recalled with reference to FIGS. 1 and 2 to better understand the advantages of the invention. Only the steps known as post-process steps are represented, that is to say the steps after the manufacture of the integrated circuit which is used to recover and treat the charges generated on the elementary capacitors which will be formed in these post-process steps. The integrated circuit is preferably produced by CMOS technology. The circuit is only represented symbolically in the form of a substrate 10 comprising a last level of metallization 12, for example a layer of aluminum, electrically connected to the subjacent layers of the integrated circuit, and a last level of insulating passivation 13, for example made of silicon oxide or silicon nitride.

The passivation layer 13 is locally open in order to expose the metal 12 in regions P1 where it is desired to produce a contact between the integrated circuit and the capacitive sensitive elements formed in the post-process, and also in the regions P2 reserved for producing pads for the external connection. In all the figures, the left-hand part makes it possible to understand how the capacitive sensitive elements are produced, whereas the right-hand part makes it possible to understand how the connection pads are produced at the same time.

The first step of the post-process in the prior art is a step of depositing a layer 14 of PMMA (polymethyl methacrylate); this layer 14 has a thickness of around 1 micrometer. The expression “depositing a layer of PMMA” is generally understood to mean the following two phases:
the spin coating of a layer of the polymer dissolved in a solvent or the deposition of a layer of precursor monomers of PMMA dissolved in a solvent;
and the polymerization step that follows, in general a heat treatment step that consists, for example, in evaporating the solvent and in annealing it.

In practice, PMMA is in the form of methyl methacrylate dissolved in polypropylene glycol monomethyl ether acetate and/or in 1-ethoxy-2-propanol acetate; these solvents evaporate at a temperature of around 150° C.

Next, the polymerized layer 14 is etched, in order to remove the PMMA in the regions P1, exposing the layer of aluminum 12 in these regions. The PMMA is retained in the regions P2 (in the form of islands of PMMA which completely cover these regions) and the layer 12 remains protected in these regions (FIG. 1a). This protection of the bared pads 12 is necessary due to the subsequent etching steps which could deteriorate the aluminum. The etching of the PMMA layer is carried out by a photolithographic process, and preferably by making sure that the PMMA layer contains adjuvants which render this layer photosensitive. This avoids the necessity of depositing a photoresist on the PMMA layer, then of irradiating the photoresist, then developing it, then etching the PMMA layer with an etchant which does not etch the resist, then of removing the residual resist layer. By rendering the PMMA layer photosensitive, it is merely necessary to irradiate the layer, to develop it, and to etch it with a product that selectively etches only the irradiated parts or conversely only the unirradiated parts.

The following step of the post-process consists in depositing a first conductive layer 16, preferably of titanium, on top of the PMMA etched pattern. This titanium layer comes into contact with the layer of aluminum 12 in the regions P1 which are exposed, but not in the regions P2 which are covered with PMMA intentionally left in place in the preceding step.

Next the layer of titanium 16 is etched. This is a chemical etching (or “wet etching”); it would not be possible to carry out a plasma etching (or “dry etching”) since the PMMA would not be resistant thereto, or more precisely would not withstand the step of removing cured photoresist residues by plasma etching after the etching of the titanium. The pattern is defined by conventional photolithography. This pattern is notably that of the individual electrodes of the array of capacitors, the dielectric of which will be the layer of P(VDF/TrFE) subsequently deposited. It will be noted that the layer of titanium is provisionally retained on top of all of the islands of PMMA that cover the regions P2, in order to protect the PMMA during the subsequent etching of the P(VDF/TrFE). This protection is necessary so as not to indirectly expose the aluminum of the regions P2 due to a deterioration of the PMMA. FIG. 1b.

It will be noted that the wet etching of titanium, in a bath typically composed of a solution of ammonium hydroxide and of hydrogen peroxide (NH₄OH, H₂O₂) must end with a step of removal of the photoresist residues which were used to define the titanium pattern to be retained. This step is carried out via a wet route with specific non-standard products since the standard compounds would attack the PMMA which is exposed wherever the titanium has been removed. The product for removing the resist residues is here an alcohol and acetone compound (non-standard product for defining a titanium pattern).

Next, a crystalline ferroelectric polymer layer 18 constituted of P(VDF/TrFE) is deposited. The copolymer is deposited dissolved in a solvent; the deposition is carried out by spin coating and drying takes place at around 80° C. and a crystallization annealing at a temperature above the melting point (147° C.) of the P(VDF/TrFE). The copolymer layer has a thickness between 1 and 5 micrometers.

The layer 18 of P(VDF/TrFE) is etched via photolithography. The removal of P(VDF/TrFE) does not pose any particular problems, the layer of PMMA being protected by the titanium on top of the pad regions P2. The etching is an etching via oxygen plasma and fluorine plasma. FIG. 1c.

The following steps of the process of the prior art are represented in FIG. 2.

A second conductive layer 20 is deposited, which layer is intended notably to form the common counter electrode of the array of ferroelectric capacitors. FIG. 2a.

This counter electrode is deposited over the entire surface of the matrix of capacitors and each elementary capacitor (constituting a pressure-sensitive or temperature-sensitive elementary detector) is formed by a first electrode which is a portion of the first conductive layer 16, and a second electrode which is a portion of the second conductive layer 20, with the dielectric layer of P(VDF/TrFE) 18 between these electrodes. The portions of layer 16 are insulated from one another and they are individually in contact with the subjacent integrated circuit by means of portions of subjacent aluminum layers 12.

The second conductive layer 20 is preferably made of titanium. It is etched in several steps in order to define the final counter electrode pattern:
firstly the titanium is wet etched after a step of deposition, exposure and development of a photolithographic resist masking the matrix of sensors and uncovering the regions P2 intended for the connection pads; the titanium is therefore only removed on top of the regions P2 but is retained wherever there is P(VDF/TrFE); in this step, not only is the second conductive layer 20 removed, but also the first conductive layer 16 where it was only used to protect the islands of PMMA during the etching of P(VDF/TrFE); FIG. 2b;
then a plasma etching is carried out in order to remove the resist residues and the thus bared layer of PMMA; the aluminum pads of the regions P2 are thus bared; FIG. 2c;
then a photolithography step is carried out again using a photoresist in order to protect the titanium of the layer 20 where it must remain in the matrix (and to protect the aluminum pads of the regions P2 during the etching which follows), and a wet etching is carried out in order to remove the titanium where it must be removed; FIG. 2d; it will be noted that a wet etching of the titanium is necessary because a dry etching using plasma tends to cure the photoresists that cover the pattern to be protected, and the removal of the thus cured photoresist residues would risk deteriorating, and notably detaching, the layer of P(VDF/TrFE) which has been bared by the removal of the titanium.

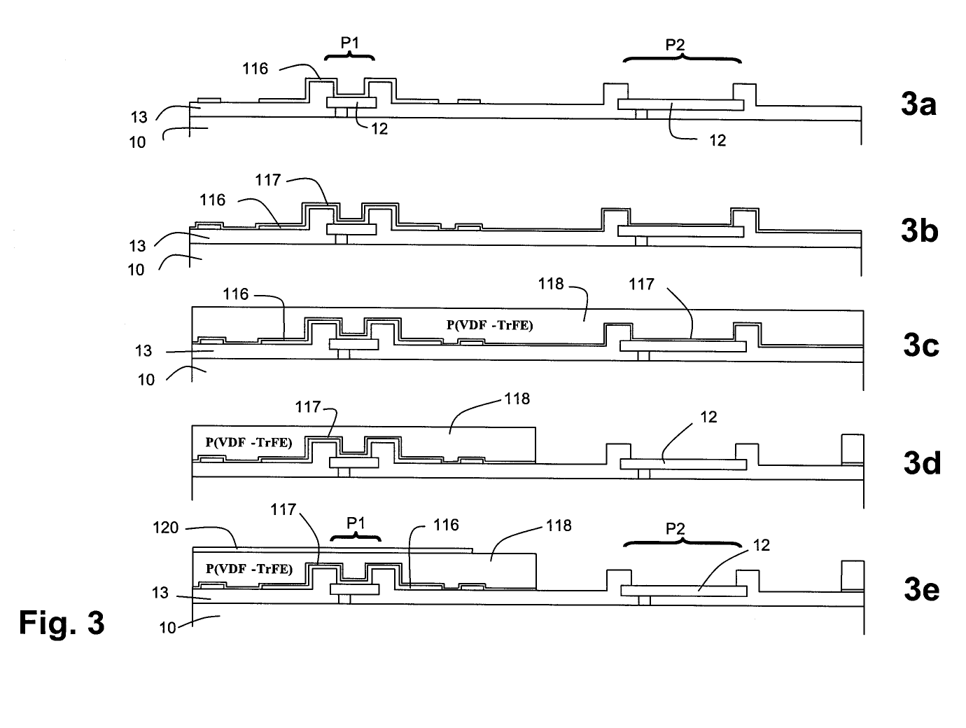

To greatly simplify the manufacture, and to improve the manufacturing yields and the service life of the products manufactured, the process now described with reference to FIG. 3 is proposed.

The same integrated circuit substrate is used as in the preceding case and the post-process steps carried out on an integrated circuit which is preferably produced by CMOS technology will be described. The circuit is here too represented in the form of a substrate 10 comprising a last level of metallization 12, for example a layer of aluminum, connected to the subjacent layers of the integrated circuit, and a last level of insulating passivation 13, for example made of silicon oxide or silicon nitride.

The passivation layer 13 is locally open to leave the metal 12 exposed in regions P1 where it is desired to produce a contact between the integrated circuit and the capacitive sensitive elements formed in the post-process, and also in regions P2 reserved for producing pads for the external connection. Here too, the left-hand part of FIG. 3 makes it possible to understand how the capacitive sensitive elements are produced, whereas the right-hand part makes it possible to understand how the connection pads are produced at the same time.

The first step of the post-process now directly comprises the deposition of a first conductive layer 116, preferably of titanium, which comes into contact with the layer of aluminum 12 where it is exposed. There is therefore no deposition of PMMA before the deposition of the first conductive layer.

Next, this layer of titanium 116 is etched. It is a dry etching, which is more standard, more precise, and better controlled than chemical etching as regards titanium. The pattern is defined by conventional photolithography with a resist that withstands plasma etching. The etching with a plasma of BCl₃/SF₆ (or SF₆ or SF₆/O₂) lasts for example one minute (for a 0.2 micrometer thickness of titanium) and is followed by a step of removing photoresist residues, with a plasma of water vapor and a nitrogen-containing compound. These steps do not risk deteriorating subjacent layers of PMMA since there are none. The etched pattern is notably that of the individual electrodes of the array of capacitors, of which the dielectric will be the layer of P(VDF/TrFE) subsequently deposited. FIG. 3a.

The titanium is not retained on top of the regions P2, so that it will not be necessary to etch a double thickness of titanium as was the case in FIG. 2a.

The remainder of the process is a deposition of a ferroelectric layer which will be constituted not only of P(VDF/TrFE) but also of a second polymer which is an adhesion promoter, that is to say a polymer that makes it possible to better attach the P(VDF/TrFE) to the subjacent surfaces which are either titanium (or even aluminum) or the passivation layer 13. Two ways of depositing the P(VDF/TrFE) and the adhesion promoter may be used:
according to the first way, the deposition is carried out in two steps, firstly a thin layer of the second adhesion-promoting polymer is deposited over a low height, preferably between 1 and 10% of the height of the subsequently deposited P(VDF/TrFE) layer, for example 0.1 micrometer for 2 micrometers of P(VDF-TrFE); the solvent is evaporated from the adhesion promoter and it is annealed at a temperature of around 240° C. which optimizes the adhesion properties; and next the P(VDF-TrFE) copolymer dissolved in a solvent is deposited; the solvent is evaporated from the P(VDF-TrFE) and it is annealed at a temperature above 150° C. (preferably around 170° C.) in order to obtain a good crystallization;
according to the second way, the deposition is carried out in a single step, an intimate mixture of the precursors of P(VDF-TrFE) and of the second adhesion-promoting polymer is deposited; the second polymer is preferably in an amount between 0.5% and 5% of the mixture by weight; the solvent is evaporated and a crystallization annealing is carried out at a temperature above 150° C. (preferably around 170° C.).

In the two hypotheses, the polymers in solution are deposited by spin coating and the crystallization of the P(VDF/TrFE) is carried out by heating; a temperature of 170° C. is generally suitable for this operation.

In FIG. 3, it has been considered that there was a two-step deposition of polymers, and FIG. 3b represents the thin layer 117 of the second adhesion-promoting polymer. This polymer may notably be PMMA, but it is deposited in a much thinner layer than in the prior art (typically having a thickness of around 0.1 to 0.2 micrometer instead of around 1 micrometer or more). The second adhesion-promoting polymer may also be a polymer that has properties similar to those of PMMA, such as the CT4000 sold by Fujifilm. These two products adhere very well to the titanium of the layer 116 and to the passivation layer 13, and also to the aluminum.

It should be emphasized here that the second polymer will not be subjected to an etching step independent of the etching of the P(VDF/TrFE), whether the deposition was carried out in two steps or in one step. In particular, besides the fact that one etching is avoided, it may also be observed that this second polymer does not need to comprise additives that render it photosensitive.

If the adhesion-promoting polymer was deposited prior to the P(VDF/TrFE), as is represented in FIG. 3b, then the deposition and the crystallization of a layer 118 of P(VDF/TrFE) is carried out. FIG. 3c.

If it was not deposited previously, a mixture of P(VDF/TrFE) and of the second polymer is deposited, and the assembly is dried by heat treatment in order to result in a single layer 118 (no layer 117) which is a crystalline mixture of the two polymers.

Then the P(VDF/TrFE) is etched in order to remove it notably above the pad regions P2 and to allow it to remain notably where it is necessary to form an array of capacitors. The pattern is defined via photolithographic means and the etching is preferably carried out by an oxygen plasma and fluorine plasma. This plasma etching also removes the layer of adhesion-promoting polymer, whether this was deposited separately or as a mixture with the layer of P(VDF/TrFE). The copolymer and the adhesion-promoting polymer remain at the location of the matrix of sensitive detectors and disappear at the location of the regions P2, which bares the aluminum in these regions. FIG. 3d.

There is therefore a single step of photoetching in order to define the pattern of P(VDF/TrFE) and the identical pattern of the adhesion-promoting polymer. The P(VDF/TrFE) is combined throughout with the adhesion promoter, whether the latter is underneath or mixed therewith.

A second conductive layer 120, which may be, like the first, made of titanium, is then deposited. This layer is notably intended to form the common counter electrode of the array of ferroelectric capacitors according to the same configuration as in the case from FIG. 2.

Finally, the second conductive layer 120 is etched. The etching pattern is defined by photolithography. It comprises the counter electrode pattern to be retained. The etching of titanium is carried out by plasma etching as for the first layer. FIG. 3e.

Only the peripheral edges of the layer of P(VDF/TrFE) risk being slightly deteriorated at the end of the plasma etching of the titanium if the photolithographic resist has been too greatly consumed during this photoetching. Unlike the case of the etching of the first conductive layer, the removal of the resist residues is carried out via a wet route rather than by a plasma of water vapor and nitrogen-containing compound, so as not to deteriorate the ferroelectric copolymer layer where it is no longer protected by the titanium. The chemical bath for removing the resist residues is preferably an ethyl lactate bath which does not detach the ferroelectric layer rendered adherent by virtue of the process according to the invention.

In this step, the second conductive layer 20 on top of the pads P2 is removed so that the aluminum of the layer 12 remains exposed with a view to welding connecting wires.

In terms of numbers of photoetching operations, there are only three operations: photoetching of the first conductive layer 116, photoetching of the layer of P(VDF/TrFE), and photoetching of the second conductive layer. Other photoetching steps and also supplementary operations such as the removal of residual layers of PMMA on top of the connection pads are eliminated. In terms of ease of implementation, it is possible to use, without any drawbacks, simpler etching methods, and notably well-controlled plasma etchings, for the conductive layers that form the electrodes of capacitors. Tests have shown the excellent adhesion of the ferroelectric layers deposited by this process, without significant modification of the dielectric and ferroelectric characteristics of the layer or the superposition of layers located between the two levels of titanium; this is despite the fact that the adhesion-promoting polymer is amorphous and that there would therefore naturally be a tendency, above all, not to use it between two electrodes of a detector operating on the principle of ferroelectricity.

In the aforegoing, it was considered that a conductive layer 116 (of titanium) was deposited in a first step of the post-process after the end of the manufacture of an integrated circuit, the last metallization level of which was the metal layer 12 used for the formation of the aluminum pads. In other words, it was considered that the integrated circuit includes a last level of metallization 12 which is not used to define the pattern of individual electrodes of the ferroelectric detectors and it is only the layer 116 that defines it. It is possible however to make provision for the post-process steps to begin with the deposition on the integrated circuit of a conductive layer 12 which defines both the individual electrodes of the ferroelectric detectors and the external connection pads. It is considered, in this case, that the integrated circuit comprises the conductive layers situated below the layer 12 but not the layer 12 and that the post-process steps begin with the deposition and the etching of the layer 12 defining the array of electrodes but also the connection pads. The deposition and the etching of the conductive layer 12 may, in this case, be followed by a step of depositing a passivation insulator and by a step of opening this insulator above the connection pads and the electrodes of the matrix array, before the step of depositing and drying the adhesion-promoting polymer and the P(VDF/TrFE) copolymer.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. A process for manufacturing a matrix sensor using a sensitive layer of a ferroelectric P(VDF/TrFE) copolymer, deposited on an integrated circuit comprising the succession of the following steps:
deposition on the integrated circuit of a first conductive layer and etching of this layer in order to form a matrix array of electrodes electrically connected to the integrated circuit;
deposition of a P(VDF/TrFE) copolymer dissolved in a solvent and also a small proportion of less than 10% of a second polymer that favors the adhesion of the P(VDF/TrFE) copolymer on the integrated circuit, and drying at high temperature in order to crystallize the copolymer;
a single step of photoetching of the crystalline P(VDF/TrFE) copolymer layer removing the copolymer and the second polymer in the regions where the copolymer should not be retained; and
deposition of a second conductive layer and etching of this layer in order to form a counter electrode for the whole of the matrix array.

2. The process as claimed in claim 1, wherein the small proportion of the second polymer favoring adhesion is constituted by a thin layer of second polymer inserted between the integrated circuit and the P(VDF/TrFE) copolymer, this thin layer having a height of around 2 to 10% of the height of the P(VDF/TrFE) layer.

3. The process as claimed in claim 2, wherein the height of the thin layer of second polymer is from 0.1 to 0.2 micrometers in thickness.

4. The process as claimed in claim 1, wherein the small proportion of the second polymer that favors the adhesion is intimately mixed with the P(VDF/TrFE) copolymer in a proportion between 0.5% and 5%.

5. The process as claimed in claim 1, wherein the second polymer is polymethyl methacrylate (PMMA) or a polymer having similar properties sold by Fujifilm under the name CT4000.

6. The process as claimed in claim 1, wherein the first and second conductive layers are made of titanium, and in that the etching of the titanium is carried out by plasma etching.

7. The process as claimed in claim 1, wherein the etching of the P(VDF/TrFE) and the simultaneous etching of the adhesion-promoting polymer is carried out by fluorinated plasma etching.

8. The process as claimed in claim 7, wherein the fluorinated plasma etching of the P(VDF/TrFE) is followed by a removal of photolithographic resist residues by oxygen plasma.

9. The process as claimed in claim 1, wherein the first conductive layer defines not only a matrix array of electrodes but also connection pads outside of the sensor.

10. A sensor comprising a matrix of pressure-sensitive or temperature-sensitive detectors, which matrix is deposited on an electronic integrated circuit, in which each detector is constituted by a capacitor formed by a first conductive electrode, a second conductive electrode and a ferroelectric layer of P(VDF/TrFE) copolymer between the electrodes, wherein the ferroelectric layer comprises a second adhesion-promoting polymer in a proportion of less than 10%, deposited under the copolymer or blended with the latter.

11. The process as claimed in claim 2, wherein the first and second conductive layers are made of titanium, and in that the etching of the titanium is carried out by plasma etching.

12. The process as claimed in claim 3, wherein the first and second conductive layers are made of titanium, and in that the etching of the titanium is carried out by plasma etching.

13. The process as claimed in claim 4, wherein the first and second conductive layers are made of titanium, and in that the etching of the titanium is carried out by plasma etching.

14. The process as claimed in claim 2, wherein the etching of the P(VDF/TrFE) and the simultaneous etching of the adhesion-promoting polymer is carried out by fluorinated plasma etching.

15. The process as claimed in claim 3, wherein the etching of the P(VDF/TrFE) and the simultaneous etching of the adhesion-promoting polymer is carried out by fluorinated plasma etching.

16. The process as claimed in claim 4, wherein the etching of the P(VDF/TrFE) and the simultaneous etching of the adhesion-promoting polymer is carried out by fluorinated plasma etching.

17. The process as claimed in claim 2, wherein the fluorinated plasma etching of the P(VDF/TrFE) is followed by a removal of photolithographic resist residues by oxygen plasma.

18. The process as claimed in claim 3, wherein the fluorinated plasma etching of the P(VDF/TrFE) is followed by a removal of photolithographic resist residues by oxygen plasma.

19. The process as claimed in claim 2, wherein the first conductive layer defines not only a matrix array of electrodes but also connection pads outside of the sensor.

20. The process as claimed in claim 3, wherein the first conductive layer defines not only a matrix array of electrodes but also connection pads outside of the sensor.
